(19) United States
(12) Patent Application Publication
(10) Pub. No.: US 2026/0206462 A1
(43) Pub. Date: Jul. 16, 2026

(54) DISPLAY DEVICE, METHOD OF MANUFACTURING THEREOF, AND ELECTRONIC DEVICE INCLUDING THE DISPLAY DEVICE

(71) Applicant: Samsung Display Co., Ltd., Yongin-Si (KR)

(72) Inventors: Yeong Woo KWON, Yongin-si (KR); Jin Su BYUN, Yongin-si (KR); Yang Ho JUNG, Yongin-si (KR); Gwang Min CHA, Yongin-si (KR)

(21) Appl. No.: 19/272,167

(22) Filed: Jul. 17, 2025

(30) Foreign Application Priority Data
Jan. 16, 2025 (KR) 10-2025-0006532

(51) Int. Cl. H10K 59/80; H10K 59/12; H10K 59/122

(52) U.S. Cl. CPC H10K 59/873; H10K 59/1201; H10K 59/122

(57) ABSTRACT

A display device includes a substrate, a contact structure, a light emitting structure, and first, second, and third encapsulation layers. The substrate includes a sub-pixel in which the contact structure is disposed. The light emitting structure is disposed on the contact structure and the first encapsulation layer is disposed on the light emitting structure. The overcoat layer is disposed on the first encapsulation layer and the conductive pattern is disposed on the overcoat layer. The conductive pattern does not overlap a light emitting area of the sub-pixel. The second encapsulation layer is disposed on the conductive pattern and the third encapsulation layer is disposed on the second encapsulation layer.

### CROSS-REFERENCE TO RELATED APPLICATION

The application claims priority under 35 U.S.C. § 119(a) to Korean patent application 10-2025-0006532 filed on Jan. 16, 2025, in the Korean Intellectual Property Office, the entire disclosure of which is incorporated herein by reference.

### BACKGROUND

### 1. Technical Field

The disclosure generally relates to a display device, a method of manufacturing the same, and an electronic device including the display device.

### 2. Related Art

In recent years, as interest in information displays increases, research and development have been consistently conducted for display devices.

### SUMMARY

Embodiments provide a display device capable of improving front light emission efficiency of each sub-pixels, a method of manufacturing the same, and an electronic device including the display device.

According to embodiments of the disclosure, a display device includes a substrate including a plurality of sub-pixels; a contact structure disposed in each of the plurality of sub-pixels; a light emitting structure disposed on the contact structure of each of the plurality of sub-pixels; a first encapsulation layer disposed on the light emitting structure and including an inorganic material; an overcoat layer disposed on the first encapsulation layer; a conductive pattern disposed on the overcoat layer, the conductive pattern does not overlap a light emitting area of each of the plurality of sub-pixels; a second encapsulation layer disposed on the conductive pattern and including an organic material; and a third encapsulation layer disposed on the second encapsulation layer.

The conductive pattern may be disposed between the overcoat layer and the second encapsulation layer. The conductive pattern may include a first inclined surface adjacent to the light emitting area, a second inclined surface facing the first inclined surface, and an upper surface connecting the first inclined surface and the second inclined surface. The first inclined surface may guide light emitted from the light emitting structure to the light emitting area of each of the sub-pixels.

The conductive pattern may have a height of about 0.5 μm or more from a surface of the overcoat layer.

A gap between the first encapsulation layer and the overcoat layer may be about 1 μm to 5 μm.

The light emitting structure may be completely covered by the first encapsulation layer.

The light emitting structure may include an anode electrode disposed on the contact structure; a pixel defining layer disposed on the anode electrode and including an opening that exposes a portion of the anode electrode to define the light emitting area; a light emitting pattern disposed between the pixel defining layer and the anode electrode; and a cathode electrode disposed on the light emitting pattern.

The first inclined surface may be located outside a side surface of the pixel defining layer defining the opening.

The contact structure may include a first layer disposed on the substrate; a second layer disposed on the first layer; and a third layer disposed between the second layer and the light emitting structure. The first to third layers may include a conductive material and be electrically connected to each other.

At least one of the first layer, the second layer, and the third layer may be in contact with the cathode electrode.

The light emitting structure may further include a sub-electrode disposed on the cathode electrode.

The display device may further include a capping layer disposed between the cathode electrode and the first encapsulation layer. The capping layer may be disposed on the cathode electrode to seal the light emitting structure.

The display device may further include a touch sensing layer disposed on the third encapsulation layer. The touch sensing layer may include a sensing pattern disposed on the third encapsulation layer and an insulating pattern disposed on the sensing pattern to cover a touch conductive pattern.

The insulating pattern may include a side surface that guides light emitted from the light emitting structure toward a front direction.

The display device may further include a sub-overcoat layer disposed on the touch sensing layer. A refractive index of the sub-overcoat layer may be greater than a refractive index of the insulating pattern.

According to embodiments of the disclosure, an electronic device includes a processor; and a display device including sub-pixels and configured to display an image based on the control of the processor. The display device may include a substrate including the sub-pixels; a contact structure disposed in each of the sub-pixels of the substrate; a light emitting structure disposed on the contact structure of each of the sub-pixels; a first encapsulation layer disposed on the light emitting structure and including an inorganic material; an overcoat layer disposed on the first encapsulation layer a conductive pattern disposed on the overcoat layer, the conductive pattern that does not overlap a light emitting area of each of the sub-pixels; a second encapsulation layer disposed on the conductive pattern; and a third encapsulation layer disposed on the second encapsulation layer.

The conductive pattern may be disposed between the overcoat layer and the second encapsulation layer. The conductive pattern may include a first inclined surface that guides light emitted from the light emitting structure in a front direction.

The conductive pattern may have a height of about 0.5 μm or more from a surface of the overcoat layer.

The light emitting structure may include an anode electrode disposed on the contact structure; a pixel defining layer disposed on the anode electrode and including an opening that exposes a portion of the anode electrode to define the light emitting area; a light emitting pattern disposed between the pixel defining layer and the anode electrode; and a cathode electrode disposed on the light emitting pattern.

The contact structure may include a first layer disposed on the substrate; a second layer disposed on the first layer; and a third layer disposed between the second layer and the light emitting structure. At least one of the first layer, the second layer, and the third layer may be in contact with the cathode electrode.

According to embodiments, the above-described display device is manufactured by providing a substrate; forming a contact structure on the substrate; forming a light emitting structure on the contact structure; forming a firs encapsulation layer on the light emitting structure; forming an overcoat layer on the first encapsulation layer; forming a conductive layer on the overcoat layer; forming a conductive pattern by removing a portion of the conductive layer through a process using a mask; forming a second encapsulation layer on the conductive pattern and the overcoat layer; and forming a third encapsulation layer on the second encapsulation layer. The conductive pattern may be disposed between the overcoat layer and the second encapsulation layer. The conductive pattern may include an inclined surface guiding light emitted from the light emitting structure in a front direction.

Embodiments according to the disclosure may guide light emitted from a light emitting structure in a front direction by disposing a conductive pattern on an overcoat layer located between the light emitting structure and a second encapsulation layer. Accordingly, light emission efficiency of each of sub-pixels (or pixels) may be improved.

The effects of the present disclosure are not limited by the foregoing, and other various effects are anticipated herein.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram a display device according to some embodiments of the disclosure.

FIG. 2 is a schematic block diagram illustrating some embodiments of one of the sub-pixels of FIG. 1.

FIG. 3 is a schematic circuit diagram illustrating some embodiments of the sub-pixel shown in FIG. 2.

FIG. 4 is a schematic plan view illustrating an embodiment of the display device of FIG. 1.

FIG. 5 is a schematic plan view illustrating an embodiment of one of the pixels of FIG. 4.

FIG. 6 is a schematic cross-sectional view taken along the line I~I′ of FIG. 5.

FIG. 7 is a schematic enlarged cross-sectional view illustrating an area EA of FIG. 6.

FIG. 8 is a schematic cross-sectional view illustrating a path of light in the display device of FIG. 7.

FIG. 9 and FIG. 10 are schematic enlarged cross-sectional views illustrating an area EA of FIG. 6.

FIG. 11 is a flowchart illustrating a method of manufacturing a display device according to embodiments.

FIG. 12 to FIG. 20 are schematic cross-sectional views illustrating process steps of a method of manufacturing a display device according to embodiments.

FIG. 21 is a schematic block diagram illustrating an electronic device in accordance with embodiments of the disclosure.

FIG. 22 shows schematic views of various embodiments of an electronic device.

### DETAILED DESCRIPTION

The disclosure may be variously altered and may take many forms, and specific embodiments are illustrated in drawings and described in detail in the detailed description. However, it is not intended to limit the disclosure to any particular form of disclosure and should be understood to include all changes, equivalents or substitutions that fall within the scope of technology of the disclosure.

In describing each drawing, similar reference symbols are used for similar components. In the accompanying drawings, the dimensions of the structures are shown enlarged from the actual size for the sake of clarity of the disclosure. Terms such as first and second may be used to describe various components, but the components should not be limited by the above terms. The above terms are used only for the purpose of distinguishing one component from another. For example, a first component may be named a second component without going beyond the scope of rights of the disclosure, and similarly, the second component may be named the first component.

In the specification, the terms “comprise,” “include,” and “have” (as well as variation such as “comprising”) shall be understood to designate the existence of a feature, a number, a step, an action, a component, a part, or a combination thereof set forth in the disclosure, and shall be understood not to preclude the possibility of the existence or addition of one or more other features or numbers, steps, motions, components, parts, or combinations thereof. In addition, when a part such as a layer, a film, an area, or a plate is referred to as being “on” another part, this includes not only the case where the part is “directly on top” of the other part, but also the case where there is another part in between. In addition, in the specification, when a part such as a layer, a film, an area, or a plate is referred to as being formed on another part, the direction in which the part is formed is not limited to an upward direction, but includes formation in a lateral or downward direction. Conversely, when a part such as a layer, a film, an area, or a plate is referred to as being “below” another part, this includes not only the case where the part is “just below” the other part, but also the case where there is still another part in between.

The expression “at least one of ~” may be intended to include the meaning of “at least one selected from a group of ~” for its meaning and interpretation. For example, “at least one of A and B” may be understood to include “A, B, or A and B”. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Hereinafter, referring to the accompanying drawings, preferred embodiments of the disclosure and other matters necessary for those skilled in the art to easily understand the disclosure will be explained in detail. In the explanation below, singular expressions also include plural expressions, unless the context clearly indicates that only the singular is included.

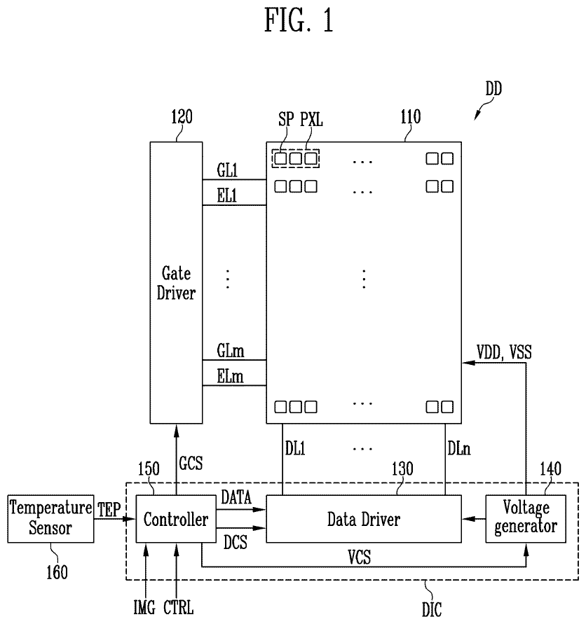

FIG. 1 is a schematic block diagram a display device DD according to some embodiments of the disclosure.

Referring to FIG. 1, the display device DD may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a particular color, such as red, green, blue, cyan, magenta, and yellow. Two or more of the sub-pixels SP may form a single pixel PXL. For example, the pixel PXL may include three sub-pixels, as shown in FIG. 1, but is not limited thereto.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal for outputting gate signals in synchronization with the timing at which data signals are applied, and the like.

In embodiments, first to m-th emission control lines EL1 to ELm connected to the sub-pixels SP in the row direction may be further provided. In this case, the gate driver 120 may include an emission control driver configured to control the first to m-th emission control lines EL1 to ELm. The emission control driver may operate under the control of the controller 150.

The gate driver 120 may be disposed on one side of the display panel 110. However, embodiments are not limited thereto. For example, the gate driver 120 may be divided into two or more physically or logically separated drivers, and the drivers may be disposed on one side of the display panel 110 and the other side of the display panel 110 opposite to the one side. As described above, the gate driver 120 may be disposed around the display panel 110 in various forms according to the embodiments.

The data driver 130 may be connected to the sub-pixels SP arranged in a column direction through the first to n-th data lines DL1 to DLn. The data driver 130 may receive image data (DATA) and a data control signal DCS from the controller 150. The data driver 130 may operate in response to the data control signal DCS. In embodiments, the data control signal DCS may include a source start pulse, a source shift clock, a source output enable signal, and the like.

The data driver 130 may use voltages from the voltage generator 140 to apply data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals. Accordingly, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to constituent elements of the display device DD. For example, the voltage generator 140 may be configured to generate a plurality of voltages by receiving an input voltage from the outside of the display device DD, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the first power voltage VDD. In other embodiments, the first power voltage VDD or the second power voltage VSS may be provided by an external device of the display device DD.

In addition, the voltage generator 140 may generate various voltages. For example, the voltage generator 140 may generate an initialization voltage applied to the sub-pixels SP. For example, upon the sensing operation to sense the electrical properties of transistors or light emitting elements of the sub-pixels SP, a set reference voltage may be applied to the first to n-th data lines DL1 to DLn, and the voltage generator 140 may generate the reference voltage.

The controller 150 may control various operations of the display device 100. The controller 150 may receive input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device DD or the display panel 110 to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, and the controller 150 may be provided as a component separated from the driver integrated circuit DIC.

The display device DD may include at least one temperature sensor 160. The temperature sensor 160 may be configured to sense a surrounding temperature and generate temperature data TEP representing the sensed temperature. In embodiments, the temperature sensor 160 may be disposed to be adjacent to the display panel 110 or the driver integrated circuit DIC.

The controller 150 may control various operations of the display device DD in response to the temperature data TEP. In embodiments, the controller 150 may adjust the luminance of an image outputted from the display panel 110 in response to the temperature data TEP. For example, the controller 150 may control the data signals and the first and second power voltages VDD and VSS by controlling components such as the data driver 130 or the voltage generator 140.

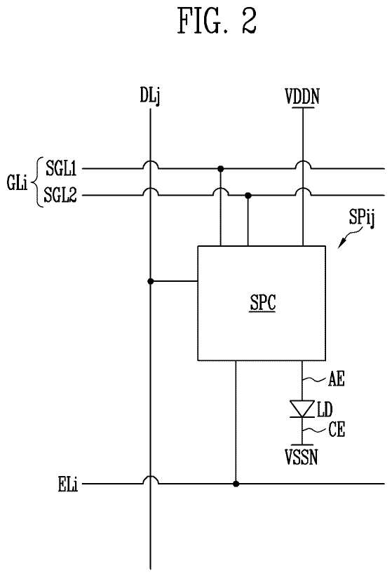

FIG. 2 is a schematic block diagram illustrating some embodiments of one of the sub-pixels of FIG. 1. In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light emitting element LD.

The light emitting element LD may be connected between a first power voltage node VDDN and a second power voltage node VSSN. In this case, the first power voltage node VDDN may be a node that transmits the first power voltage VDD of FIG. 1, and the second power voltage node VSSN may be a node that transmits the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may be configured to control the light emitting element LD according to signals received through these signal lines.

The sub-pixel circuit SPC may operate in response to a gate signal received through the i-th gate line GLi. The i-th gate line GLi may include one or more sub-gate lines. In embodiments, as shown in FIG. 2, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. When the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first sub-gate line SGL1 and the second sub-gate line SGL2. In response to the emission control signal received through the i-th emission control line ELi, the sub-pixel circuit SPC may adjust a current flowing from the first power voltage node VDDN to the second power voltage node VSSN through the light emitting element LD according to the stored voltage. Accordingly, the light emitting element LD may generate light of luminance corresponding to the data signal.

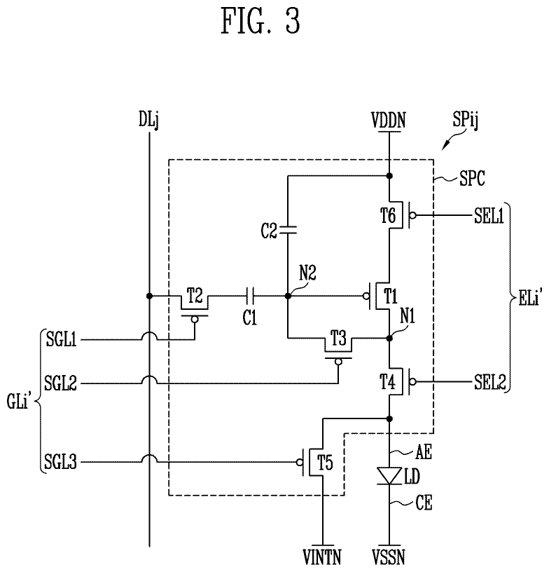

FIG. 3 is a schematic circuit diagram illustrating some embodiments of the sub-pixel SPij shown in FIG. 2.

Referring to FIG. 3, the sub-pixel SPij may include a sub-pixel circuit SPC and a light emitting element LD.

The sub-pixel circuit SPC may be connected to an i-th gate line GLi′, an i-th emission control line EL1′, and the j-th data line DLj. Compared to the i-th gate line GLi of FIG. 2, the i-th gate line GLi′ may further include a third sub-gate line SGL3. Compared to the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 may be connected between the first power voltage node VDDN and a first node N1. A gate of the first transistor T1 may be connected to a second node N2, and thus the first transistor T1 may be turned on according to a voltage level of the second node N2. The first transistor T1 may be referred to as a driving transistor.

The second transistor T2 may be connected between the j-th data lines DLj and the second node N2. A gate of the second transistor T2 may be connected to the first sub-gate line SGL1, and thus the second transistor T2 may be turned on in response to a gate signal of the first sub-gate line SGL1. The second transistor T2 may be referred to as a switching transistor.

The third transistor T3 may be connected between the first node N1 and the second node N2. A gate of the third transistor T3 may be connected to the second sub-gate line SGL2, and thus the third transistor T3 may be turned on in response to a gate signal of the second sub-gate line SGL2.

The fourth transistor T4 may be connected between the first node N1 and the anode electrode AE of the light emitting element LD. A gate of the fourth transistor T4 may be connected to the second sub-emission control line SEL2, and thus the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In embodiments, the initialization voltage may be provided by the voltage generator 140 of FIG. 1. In other embodiments, the initialization voltage may be provided by an external device of the display device DD. A gate of the fifth transistor T5 may be connected to the third sub-gate line SGL3, and thus the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and thus the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As described above, the sub-pixel circuit SPC may include the first to sixth transistors T1 to T6, and the first and second capacitors C1 and C2. However, embodiments are not limited thereto. The sub-pixel circuit SPC may be implemented as any of various types of circuits including a plurality of transistors and one or more capacitors. For example, the sub-pixel circuit SPC may include two transistors and one capacitor. According to embodiments of the sub-pixel circuit SPC, the number of sub-gate lines included in the i-th gate line GLi′ and the number of sub-emission control lines included in the i-th emission control line ELi′ may be variable.

The first to sixth transistors T1 to T6 may be P-type transistors. Each of the first to sixth transistors T1 to T6 may be a metal oxide silicon field effect transistor (MOSTEF). However, embodiments are not limited thereto. For example, at least one of the first to sixth transistors T1 to T6 may be replaced with an N-type transistor.

In embodiment, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode electrode AE, the cathode electrode CE, and a light emitting layer. The light emitting layer may be disposed between the anode electrode AE and the cathode electrode CE. After the data signal transferred through the j-th data line DLj is reflected in a voltage of the second node N2, when the emission control signals of the first and second sub-emission control lines SEL1 and SEL2 are enabled to a low level, the fourth and sixth transistors T4 and T6 may be turned on. In addition, the first transistor T1 may be turned on according to the voltage of the second node N2, and thus a current may flow from the first power voltage node VDDN to the second power voltage node VSSN. The light emitting element LD may emit light according to the amount of the flowing current.

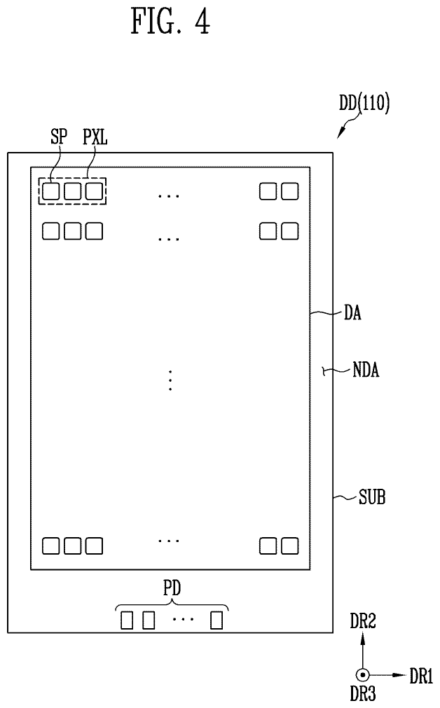

FIG. 4 is a schematic plan view illustrating an embodiment of the display device DD of FIG. 1. For convenience, FIG. 4 schematically illustrates the structure of a display area DA of the display device DD where an image is displayed, for example, the structure of the display panel 110 provided in the display device DD.

Referring to FIG. 4, the display panel 110 may include a display area DA and a non-display device NDA. The display panel 110 may display an image through the display area DA. The non-display area NDA may be disposed around the display area DA.

The display panel 110 may include a substrate SUB, the sub-pixels SP, and pads PD.

When the display panel 110 is used as a display screen of a head mounted display (HMD), a virtual reality (VR) device, a mixed reality (MR) device, an augmented reality (AR) device, or the like, the display panel 110 may be positioned very close to user's eyes. In this case, sub-pixels SP of a relatively high integration degree are required. In order to increase an integration degree of the sub-pixels SP, the substrate SUB may be provided as a silicon substrate (or a silicon wafer), but is not limited thereto.

The sub-pixels SP may be disposed in the display area DA on the substrate SUB. The sub-pixels SP may be arranged in a matrix shape along a first direction DR1 and a second direction DR2 intersecting the first direction DR1. However, embodiments are not limited thereto. For example, the sub-pixels SP may be arranged in a zigzag pattern in the first direction DR1 and the second direction DR2. For example, the sub-pixels SP may be disposed in a PENTILE™ pattern. The first direction DR1 may be a row direction, and the second direction DR2 may be a column direction. A third direction DR3 may be defined as normal to the plane defined by the first and second directions DR1 and DR2.

Two or more sub-pixels SP among the plurality of sub-pixels SP may configure one pixel PXL.

Components for controlling the sub-pixels SP may be disposed in the non-display area NDA on the substrate SUB. For example, wirings which are connected to the sub-pixels SP, such as the first to m-th gate lines GL1 to GLm and the first to n-th data lines DL1 to DLm of FIG. 1, may be disposed in the non-display area NDA.

At least one of the gate driver 120, the data driver 130, the voltage generator 140, the controller 150 and the temperature sensor 160 of FIG. 1 may be integrated in the non-display area NDA of the display panel 110. In embodiments, the gate driver 120 of FIG. 1 may be mounted in the display panel 110, and may be disposed in the non-display area NDA. In other embodiments, the gate driver 120 may be implemented as an integrated circuit which is separate from the display panel 110. In embodiments, the temperature sensor 160 may be disposed in the non-display area NDA to sense a temperature of the display panel 110.

The pads PD may be disposed in the non-display area NDA on the substrate SUB. The pads PD may be electrically connected to the sub-pixels SP via wirings. For example, the pads PD may be connected to the sub-pixels SP through the first to n-th data lines DL1 to DLn.

The pads PD may interface the display panel 110 to other components of the display device DD. In embodiments, voltages and signals necessary for an operation of components included in the display panel 110 may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted in the display panel 110, the gate control signal GCS may be transmitted from the driver integrated circuit DIC to the gate driver 120 through the pads PD.

In embodiments, a circuit board may be electrically connected to the pads PD using a conductive adhesive member such as an anisotropic conductive film. At this time, the circuit board may be a flexible printed circuit board (FPCB) or a flexible film having a flexible material. The driver integrated circuit DIC may be mounted on the circuit board to be electrically connected to the pads PD.

In embodiments, the display area DA may have various shapes. The display area DA may have a closed loop shape including straight or curved sides. For example, the display area DA may have shapes such as a polygon, a circle, a semicircle, and an ellipse.

In embodiments, the display panel 110 may have a flat display surface. In other embodiments, the display panel 110 may have a display surface that is at least partially round. In embodiments, the display panel 110 may be bendable, foldable, or rollable. In these cases, the display panel 110 or the substrate SUB may include materials having flexible properties.

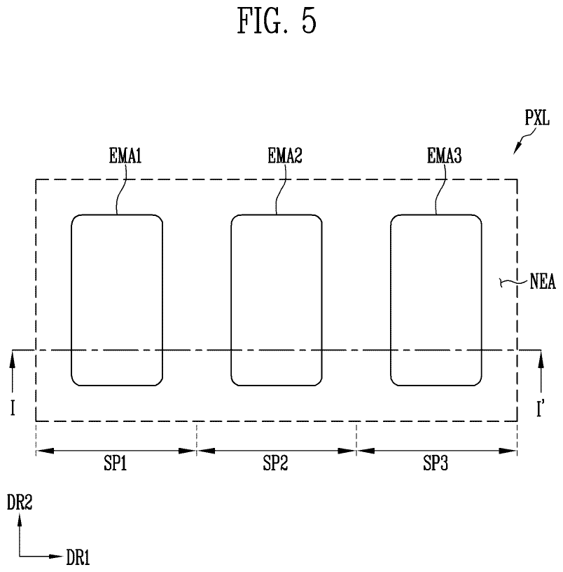

FIG. 5 is a schematic plan view illustrating an embodiment of one of the pixels of FIG. 4.

Referring to FIGS. 4 and 5, the pixel PXL may include a first sub-pixel SP1, a second sub-pixel SP2, and a third sub-pixel SP3 arranged in the first direction DR1.

The first sub-pixel SP1 may include a first light emitting area EMA1 and a non-light emitting area NEA around the first light emitting area EMA. The second sub-pixel SP2 may include a second light emitting area EMA2 and a non-light emitting area NEA around the second light emitting area EMA2. The third sub-pixel SP3 may include a third light emitting area EMA3 and a non-light emitting area NEA around the third light emitting area EMA3.

The first light emitting area EMA1 may be an area where light is emitted from a light emitting element (see “LD” in FIG. 2) corresponding to the first sub-pixel SP1. The second light emitting area EMA2 may be an area where light is emitted from a light emitting element LD corresponding to the second sub-pixel SP2. The third light emitting area EMA3 may be an area where light is emitted from a light emitting element LD corresponding to the third sub-pixel SP3.

The first sub-pixel SP1, the second sub-pixel SP2, and the third sub-pixel SP3 may substantially have the same area, but the embodiment is not limited thereto. In some embodiments, the second sub-pixel SP2 may have an area greater than an area of the first sub-pixel SP1, and the third sub-pixel SP3 may have an area greater than the area of the second sub-pixel SP2.

The first sub-pixel SP1, the second sub-pixel SP2, and the third sub-pixel SP3 may have a polygonal shape. For example, the first sub-pixel SP1, the second sub-pixel SP2, and the third sub-pixel SP3 may have a quadrangular shape or a hexagonal shape, but the embodiment is not limited thereto.

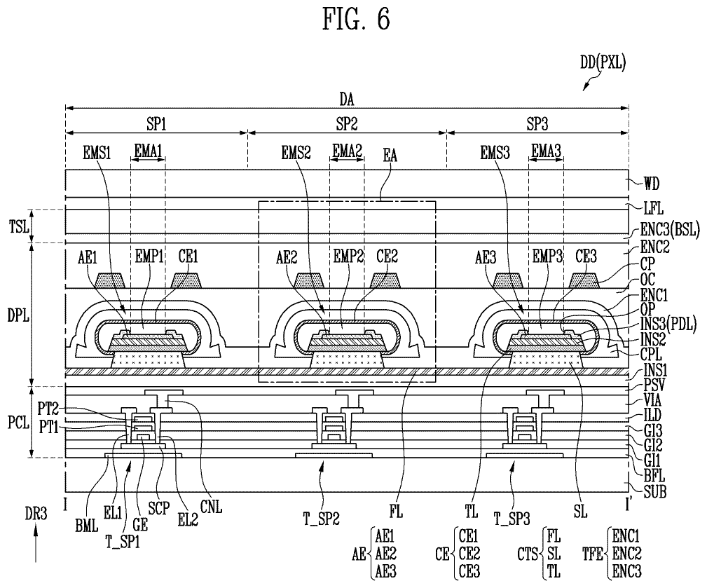

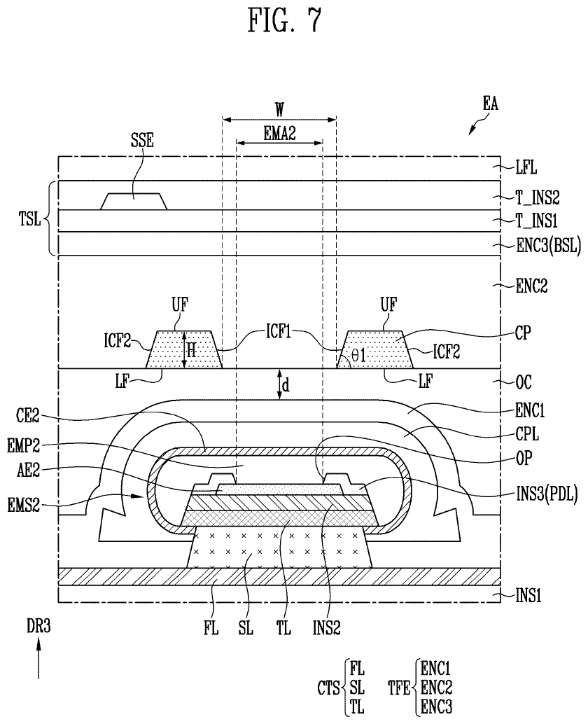

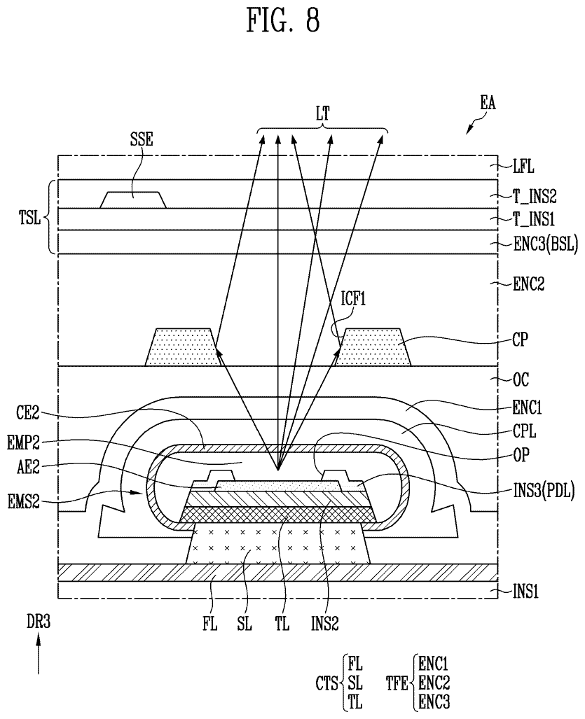

FIG. 6 is a schematic cross-sectional view taken along the line I~I′ of FIG. 5. FIG. 7 is a schematic enlarged cross-sectional view illustrating an area EA of FIG. 6. FIG. 8 is a schematic cross-sectional view illustrating a path of light in display device of FIG. 7.

In FIG. 6 to FIG. 8, the cross-sectional structure (or stacked structure) of the display device DD is simply illustrated with a focus on the pixel PXL included in the display device DD, and the thickness direction of the substrate SUB is shown in the third direction DR3, for convenience of description.

Referring to FIG. 5 to FIG. 8, the display device DD may include at least one or more pixels PXL disposed in the display area DA.

The pixel PXL may include at least one or more sub-pixels SP. For example, the pixel PXL may include a first sub-pixel SP1, a second sub-pixel SP2, and a third sub-pixel SP3. In embodiments, the first sub-pixel SP1 may be a red sub-pixel, the second sub-pixel SP2 may be a green sub-pixel, and the third sub-pixel SP3 may be a blue sub-pixel, but are not limited thereto.

The display device DD may include a substrate SUB, a pixel circuit layer PCL, and a display element layer DPL.

The substrate SUB may allow transmission of light by including a transparent insulating material. The substrate SUB may be a rigid substrate or a flexible substrate.

The rigid substrate may, for example, be one of glass substrates, quartz substrates, glass-ceramic substrates, and crystalline glass substrates.

The flexible substrate may be one of a film substrate including a polymeric organic material or a plastic substrate. For example, the flexible substrate may include at least any one of polystyrene, polyvinyl alcohol, polymethyl methacrylate, polyethersulfone, polyacrylate, polyetherimide, polyethylene naphthalate, polyethylene terephthalate, polyphenylene sulfide, polyacrylate, polyimide, polycarbonate, triacetate cellulose, and cellulose acetate propionate.

The pixel circuit layer PCL of the first to third sub-pixels SP1 to SP3 may be disposed on the substrate SUB. At least one or more insulating layers may be disposed on the pixel circuit layer PCL. The insulating layers may include a buffer layer BFL, a first gate insulating layer GI1, a second gate insulating layer GI2, a third gate insulating layer GI3, an interlayer insulating layer ILD, a via layer VIA, a passivation layer PSV, which are stacked in sequence on the substrate SUB along the third direction DR3. The insulating layers disposed on the pixel circuit layer PCL are not limited to the embodiment described above, and other insulating layers may be added or some insulating layers may be omitted.

The buffer layer BFL may be disposed on the substrate SUB. The buffer layer BFL may prevent impurities from diffusing into circuit elements (or driving elements) constituting the sub-pixel circuit (see “SPC” in FIG. 2), for example, transistors. The buffer layer BFL may be an inorganic insulating film containing an inorganic substance (or material). The buffer layer BFL may include at least one of silicon nitride (SiNₓ), silicon oxide (SiOₓ), silicon oxynitride (SiOₓN_{y}), and aluminum oxide (AlOₓ). The buffer layer BFL may be provided as a single layer, but may also be provided as a multi-layer of at least two or more layers. The buffer layer BFL may be omitted depending on the material, process conditions, etc., of the substrate SUB.

The first gate insulating layer GI1 may be disposed on the buffer layer BFL. The first gate insulating layer GI1 may include the same material as the buffer layer BFL or may include a suitable (or selected) material out of the materials exemplified as the constituent materials of the buffer layer BFL. For example, the first gate insulating layer GI1 may be an inorganic film containing an inorganic material.

The second gate insulating layer GI2 may be disposed on the first gate insulating layer GI1. The second gate insulating layer GI2 may include the same material as the first gate insulating layer GI1 or may include one or more suitable (or selected) materials out of the materials exemplified as the constituent materials of the first gate insulating layer GI1.

The third gate insulating layer GI3 may be disposed on the second gate insulating layer GI2. The third gate insulating layer GI3 may be an inorganic film including an inorganic material or an organic film including an organic material.

The interlayer insulating layer ILD may be disposed on the third gate insulating layer GI3. The interlayer insulating layer ILD may include the same material as the third gate insulating layer GI3 or may include one or more suitable (or selected) materials out of the materials exemplified as the constituent materials of the buffer layer BFL.

The via layer VIA may be disposed on the interlayer insulating layer ILD. The via layer VIA may be an inorganic film including an inorganic material or an organic film including an organic material. The inorganic film may include, for example, at least one of silicon oxide, silicon nitride, silicon oxynitride, and aluminum oxide. The organic film may include, for example, at least one of polyacrylate resins, epoxy resins, phenolic resins, polyamide resins, polyimide resins, unsaturated polyester resins, poly-phenylene ether resins, poly-phenylene sulfide resins, and benzocyclobutene resins. In one or more embodiments, the via layer VIA may be an organic film including an organic material.

The passivation layer PSV may disposed on the via layer VIA. The passivation layer PSV may be an inorganic film including an inorganic material or an organic film including an organic material. For example, the passivation layer PSV may be an inorganic film.

Circuit elements (or driving elements) of each of the first to third sub-pixels SP1 to SP3 may be disposed in the pixel circuit layer PCL. For example, a transistor T_SP1 of the first sub-pixels SP1, a transistor T_SP2 of the second sub-pixel SP2, and a transistor T_SP3 of the third sub-pixel SP3 may be disposed in the pixel circuit layer PCL. The transistor T_SP1 of the first sub-pixel SP1 may be one of the transistors included in the sub-pixel circuit SPC of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 6, one of the transistors of each of the first to third sub-pixels SP1 to SP3 is shown, and the rest of the circuit elements are omitted, for clear and concise description.

The transistor T_SP1 of the first sub-pixel SP1 may include a semiconductor pattern SCP, a gate electrode GE, a first terminal EL1, and a second terminal EL2.

The gate electrode GE may be disposed on the first gate insulating layer GI1 and covered by the second gate insulating layer GI2. For example, the gate electrode GE may be a first conductive layer C1 (or a first gate conductive layer) located between the first gate insulating layer GI1 and the second gate insulating layer GI2. The gate electrode GE may overlap an active pattern of the semiconductor pattern SCP.

The pixel circuit layer PCL may include a first pattern PT1 disposed between the second gate insulating layer GI2 and the third gate insulating layer GI3. The first pattern PT1 may be formed of a second conductive layer (or a second gate conductive layer). In other embodiments, the first pattern PT1 may overlap the gate electrode GE with the second gate insulating layer GI2 interposed therebetween, thereby forming a capacitor. In addition, the pixel circuit layer PCL may include a second pattern PT2 disposed between the third gate insulating layer GI3 and the interlayer insulating layer ILD. The second pattern PT2 may be formed of a third conductive layer (or a third gate conductive layer). In other embodiments, the second pattern PT2 may be used as signal lines, connection members, or the like electrically connected to the transistors.

The semiconductor pattern SCP may be disposed on the buffer layer BFL and covered by the first gate insulating layer GI1. The semiconductor pattern SCP may be a semiconductor layer made of polysilicon, amorphous silicon, an oxide semiconductor, or the like. The semiconductor pattern SCP may include an active pattern, a first contact area, and a second contact area. The active pattern, the first contact area, and the second contact area may be formed of a semiconductor layer that is not doped with impurities or doped with impurities. For example, the first contact area and the second contact area may be formed of a semiconductor layer that is doped with impurities, and the active pattern may be an area doped at a lower concentration than the first and second contact areas. Accordingly, the conductivity of the first and second contact areas may be greater than the conductivity of the active pattern. The first and second contact areas may be source/drain areas (or source/drain electrodes) of the transistor T_SP1 of the first sub-pixel SP1.

The active pattern of the semiconductor pattern SCP may be an area overlapping the gate electrode GE and may be a channel area. The first contact area of the semiconductor pattern SCP may contact one end of the active pattern. The first contact area may be electrically connected to the first terminal EL1. The second contact area of the semiconductor pattern SCP may contact the other end of the active pattern. The second contact area may be electrically connected to the second terminal EL2.

The first terminal EL1 may be provided or formed on the interlayer insulating layer ILD. For example, the first terminal EL1 may be formed of a fourth conductive layer (or a first source-drain conductive layer) disposed between the interlayer insulating layer ILD and the via layer VIA. The first terminal EL1 may contact the first contact area of the semiconductor pattern SCP through a contact hole penetrating the interlayer insulating layer ILD, the third gate insulating layer GI3, the second gate insulating layer GI2, and the first gate insulating layer GI1.

The second terminal EL2 may be provided or formed on the interlayer insulating layer ILD. For example, the second terminal EL2 may be formed of the fourth conductive layer disposed between the interlayer insulating layer ILD and the via layer VIA. The second terminal EL2 may contact the second contact area of the semiconductor pattern SCP through a contact hole penetrating the interlayer insulating layer ILD, the third gate insulating layer GI3, the second gate insulating layer GI2, and the first gate insulating layer GI1.

The second terminal EL2 may be electrically connected to a connection line CNL disposed on the via layer VIA. The connection line CNL may be a fifth conductive layer (or a second source-drain conductive layer) disposed between the via layer VIA and the passivation layer PSV.

According to embodiments, a bottom metal pattern BML may be disposed at the bottom of the transistor T_SP1 of the first sub-pixel SP1 described above. The bottom metal pattern BML may be a dummy conductive layer located between the substrate SUB and the buffer layer BFL. According to embodiments, the bottom metal pattern BML may be electrically connected to some components disposed in the pixel circuit layer PCL.

As the gate electrode GE, the first terminal EL1, and the second terminal EL2 are electrically connected to other circuit elements or wiring lines, the transistor T_SP1 of the first sub-pixel SP1 may be provided as one of the transistors constituting the sub-pixel circuit SPC of the first sub-pixel SP1.

Each of the transistor T_SP2 of the second sub-pixel SP2 and the transistor T_SP3 of the third sub-pixel SP3 may be configured substantially the same as the transistor T_SP1 of the first sub-pixel SP1.

As described above, the pixel circuit layer PCL may include circuit elements of each of the first to third sub-pixels SP1 to SP3.

The display element layer DPL may be disposed on the pixel circuit layer PCL. The display element layer DPL may include a contact structure CTS, a light emitting structure, an encapsulation layer TFE. In addition, the display element layer DPL may include a first insulating layer INS1, a second insulating layer INS2, and a third insulating layer INS3.

The first insulating layer INS1 may be disposed on the passivation layer PSV of the pixel circuit layer PCL. The first insulating layer INS1 may include an inorganic film including an inorganic material.

The contact structure CTS of each of the first to third sub-pixels SP1 to SP3 may be disposed on the first insulating layer INS1.

The contact structure CTS may include a first layer FL, a second layer SL, and a third layer TL arranged sequentially along the third direction DR3.

The first layer FL may be a common layer commonly provided to the first to third sub-pixels SP1 to SP3. The first layer FL may be provided in the form of a plate over the display area DA.

The second layer SL may be disposed on the first layer FL. The second layer SL of each sub-pixel may be separated from the second layer SL of adjacent sub-pixels. For example, the second layer SL of the first sub-pixel SP1 may be separated from the second layer SL of the second sub-pixel SP2 and the second layer SL of the third sub-pixel SP3. The second layer SL of the first sub-pixel SP1, the second layer SL of the second sub-pixel SP2, and the second layer SL of the third sub-pixel SP3 may be spaced apart from each other.

The second layer SL may include a lower surface in contact with the first layer FL and an upper surface in contact with a third layer TL. The second layer SL may have a polygonal, for example, trapezoidal shape that becomes narrower from the lower surface toward the upper surface. A side surface (or an edge) of the second layer SL may be positioned more inward than a side surface (or an edge) of the third layer TL. In this case, the side surface of the third layer TL may protrude more than the side surface of the second layer SL.

The third layer TL may be disposed on the second layer SL. The third layer TL of each sub-pixel may be separated from the third layer TL of adjacent sub-pixels. For example, the third layer TL of the first sub-pixel SP1 may be separated from the third layer TL of the second sub-pixel SP2 and the third layer TL of the third sub-pixel SP3. The third layer TL of the first sub-pixel SP1, the third layer TL of the second sub-pixel SP2, and the third layer TL of the third sub-pixel SP3 may be spaced apart from each other.

The first layer FL, the second layer SL, and the third layer TL may include a conductive material. The first layer FL, the second layer SL, and the third layer TL may be electrically connected to each other. At least one of the first layer FL, the second layer SL, and the third layer TL may be electrically connected to a cathode electrode CE of each sub-pixel. For example, in the first sub-pixel SP1 the third layer TL may be electrically connected to a first cathode electrode CE1, in the second sub-pixel SP2 the third layer TL may be electrically connected to a second cathode electrode CE2, and in the third sub-pixel SP3 the third layer TL may be electrically connected to a third cathode electrode CE3.

The contact structure CTS including the first layer FL, the second layer SL, and the third layer TL may form an electrical path of the cathode electrode CE.

The second insulating layer INS2 may be disposed on the third layer TL. The second insulating layer INS2 may be disposed on the third layer TL to cover the third layer TL. The second insulating layer INS2 may be an inorganic film including an inorganic material. The second insulating layer INS2 of each sub-pixel may be separated from the second insulating layer INS2 of adjacent sub-pixels. The second insulating layer INS2 may be located between the third layer TL and an anode electrode AE of each sub-pixel to electrically insulate the third layer TL from the third anode electrode AE3.

The anode electrode AE may be disposed on the second insulating layer INS2. For example, a first anode electrode AE1 may be disposed on the second insulating layer INS2 of the first sub-pixel SP1, a second anode electrode AE2 may be disposed on the second insulating layer INS2 of the second sub-pixel SP2, and a third anode electrode AE3 may be disposed on the second insulating layer INS2 of the third sub-pixel SP3.

Each of the first to third anode electrodes AE1 to AE3 may have a shape similar to the first to third light emitting areas EMA1 to EMA3 when viewed in the third direction DR3. For example, the first anode electrode AE1 may have a shape similar to the first light emitting area EMA1 when viewed in the third direction DR3, the second anode electrode AE2 may have a shape similar to the second light emitting area EMA2 when viewed in the third direction DR3, and the third anode electrode AE3 may have a shape similar to the third light emitting area EMA3 when viewed in the third direction DR3, but is not limited thereto.

Each of the first to third anode electrodes AE1 to AE3 may be electrically connected to a corresponding sub-pixel circuit SPC to be supplied with a driving current. The first anode electrode AE1 may be electrically connected to the transistor T_SP1 of the first sub-pixel SP1. The second anode electrode AE2 may be electrically connected to the transistor T_SP2 of the second sub-pixel SP2. The third anode electrode AE3 may be electrically connected to the transistor T_SP3 of the third sub-pixel SP3. Each of the first to third anode electrodes AE1 to AE3 may include, but is not limited thereto, an opaque conductive material capable of reflecting light. According to embodiments, each of the first to third anode electrodes AE1 to AE3 may include a transparent conductive material.

The third insulating layer INS3 may be disposed on the first to third anode electrodes AE1 to AE3. The third insulating layer INS3 may include an opening OP exposing a portion of the first anode electrode AE1, a portion of the second anode electrode AE2, and a portion of the third anode electrode AE3. The third insulating layer INS3 may be a pixel defining layer PDL that defines (or partitions) the light emitting area of each of the first to third sub-pixels SP1 to SP3. For example, the third insulating layer INS3 may define the first light emitting area EMA1 of the first sub-pixel SP1, the second light emitting area EMA2 of the second sub-pixel SP2, and the third light emitting area EMA3 of the third sub-pixel SP3.

The third insulating layer INS3 may be an inorganic film including an inorganic material. The third insulating layer INS3 of each sub-pixel may be separated from the third insulating layer INS3 of adjacent sub-pixels. For example, the third insulating layer INS3 of the first sub-pixel SP1 may be separated from the third insulating layer INS3 of the second sub-pixel SP2 and the third insulating layer INS3 of the third sub-pixel SP3. The third insulating layer INS3 may surround edges of each of the first to third anode electrodes AE1 to AE3.

A side surface (or an edge) of the third insulating layer INS3, a side surface (or an edge) of the second insulating layer INS2, and the side surface (or the edge) of the third layer TL may be positioned on the same line along a direction inclined in the third direction DR3. However, embodiments are not limited thereto. The side surface of the third insulating layer INS3 may protrude more than the side surface (or the edge) of the second layer SL. Accordingly, the third insulating layer INS3 (or the pixel defining layer PDL) may form a tip structure protruding from the second layer SL together with the second insulating layer INS2 or the third layer TL.

A light emitting pattern may be disposed on the third insulating layer INS3. For example, a first light emitting pattern EMP1 may be disposed on the third insulating layer INS3 of the first sub-pixel SP1, a second light emitting pattern EMP2 may be disposed on the third insulating layer INS3 of the second sub-pixel SP2, and a third light emitting pattern EMP3 may be disposed on the third insulating layer INS3 of the third sub-pixel SP3. The first light emitting pattern EMP1, the second light emitting pattern EMP2, and the third light emitting pattern EMP3 may be separated from each other. For example, the first to third light emitting patterns EMP1 to EMP3 may be separated from each other by the tip structure of the pixel defining layer PDL, the second insulating layer INS2, and the third layer TL. Accordingly, the first to third light emitting patterns EMP1 to EMP3 may be spaced apart from each other. The first to third light emitting patterns EMP1 to EMP3 may generate light of red, green, and blue colors.

The cathode electrode CE may be disposed on the first to third light emitting patterns EMP1 to EMP3. The cathode electrode CE may be directly disposed on a corresponding light emitting pattern. For example, a first cathode electrode CE1 may be directly disposed on the first light emitting pattern EMP1, a second cathode electrode CE2 may be directly disposed on the second light emitting pattern EMP2, and a third cathode electrode CE3 may be directly disposed on the third light emitting pattern EMP3. The first to third cathode electrodes CE1 to CE3 may be separated from each other. The first cathode electrode C1, the second cathode electrode C2, and the third cathode electrode C3 may be spaced from each other.

The first to third cathode electrodes CE1 to CE3 may be in contact with a corresponding third layer TL. The first to third cathode electrodes CE1 to CE3 may be electrically connected to the corresponding third layer TL. The first cathode electrode CE1, the second cathode electrode CE2, and the third cathode electrode CE3 may be electrically connected to the first layer FL through the third layer TL and the second layer SL. The first cathode electrode CE1, the second cathode electrode CE2, and the third cathode electrode CE3 may be connected to each other through the first layer FL.

The first to third cathode electrodes CE1 to CE3 may include a transparent conductive material. For example, each of the first to third cathode electrodes CE1 to CE3 may include at least one of a variety of transparent conductive materials, including indium tin oxide, indium zinc oxide, indium tin zinc oxide, aluminum zinc oxide, gallium zinc oxide, zinc tin oxide, or gallium tin oxide. The first to third cathode electrodes CE1 to CE3 are shown as a single layer, but are not limited thereto. According to embodiments, the first to third cathode electrodes CE1 to CE3 may be configured as multiple layers including a first metal layer and a second metal layer stacked sequentially. In this case, the first metal layer may be disposed between the corresponding light emitting pattern and the second metal layer, the second metal layer may be disposed between the first metal layer and a capping layer CPL.

The first anode electrode AE1, the first light emitting pattern EMP1, and the first cathode electrode CE1 may form a first light emitting structure EMS1. The second anode electrode AE2, the second light emitting pattern EMP2, and the second cathode electrode CE2 may form a second light emitting structure EMS2. The third anode electrode AE3, the third light emitting pattern EMP3, and the third cathode electrode CE3 may form a third light emitting structure EMS3.

The capping layer CPL may be disposed on the first to third cathode electrodes CE1 to CE3. The capping layer CPL may be an inorganic capping layer including an inorganic material, an organic capping layer including an organic material, or a composite capping layer including both organic and inorganic materials. The capping layer CPL may be in contact with the side surface of the second layer SL. The capping layer CPL may be disposed on the first to third light emitting structures EMS1 to EMS3 to cover the first to third light emitting structures EMS1 to EMS3. The capping layer CPL may be configured to protect the first to third light emitting structures EMS1 to EMS3 from external oxygen and moisture, etc. The capping layer CPL may have a thickness of about 1.5 μm in the third direction DR3, but is not limited thereto.

A first encapsulation layer ENC1 may be disposed on the capping layer CPL. The first encapsulation layer ENC1 may be disposed on the capping layer CPL. The first encapsulation layer ENC1 may be provided in common to the first to third sub-pixels SP1 to SP3. The first encapsulation layer ENC1 may be an inorganic layer including an inorganic material. For example, the inorganic layer may include silicon nitride, silicon oxide, silicon oxynitride, or the like. The first encapsulation layer ENC1 together with the capping layer CPL may protect the first to third light emitting structures EMS1 to EMS3 from external oxygen or moisture, etc. In addition, the first encapsulation layer ENC1 and the capping layer CPL may completely cover the first to third light emitting structures EMS1 to EMS3 so that the first to third light emitting structures EMS1 to EMS3 are not affected in the process of forming the configurations disposed on the first to third light emitting structures EMS1 to EMS3. The first encapsulation layer ENC1 may have a thickness of about 0.7 μm in the third direction DR3, but is not limited thereto.

An overcoat layer OC may be disposed on the first encapsulation layer ENC1. The overcoat layer OC may smooth the steps by the components disposed thereunder. The overcoat layer OC may cover the first encapsulation layer ENC1, the first to third light emitting structures EMS1 to EMS3, the contact structure CTS. The overcoat layer OC may include a variety of materials suitable for protecting the underlying layers thereof from foreign substances such as dust, moisture, etc. For example, the overcoat layer OC may be an organic film including an organic material.

A conductive pattern CP may be disposed on the overcoat layer OC. The conductive pattern CP may be disposed adjacent to a boundary area between adjacent sub-pixels. For example, the conductive pattern CP may be disposed on the overcoat layer OC so as not to overlap with the light emitting area of the first to third sub-pixels SP1 to SP3. The conductive pattern CP may be disposed on the overcoat layer OC so as not to overlap with each of the first light emitting area EMA1, the second light emitting area EMA2, and the third light emitting area EMA3.

The conductive pattern CP3 may include an opaque metal suitable for reflecting light emitted from the first to third light emitting structures EMS1 to EMS3 in the front direction (or light emitting area) of each sub-pixel. The conductive pattern CP3 may be, but is not limited thereto, a single layer. According to embodiments, the conductive pattern CP may be configured as multiple layers in which at least two or more of metals, alloys, conductive oxide, and conductive polymers are stacked.

In each of the first to third sub-pixels SP1 to SP3, the conductive pattern CP may be spaced apart from adjacent conductive patterns CP by a predetermined distance. When viewed in cross sectional, a gap (or a width W) between two adjacent conductive patterns CP in each of the first to third sub-pixels SP1 to SP3 may be larger than an area of the light emitting area of each sub-pixel.

Each conductive pattern CP may include a first inclined surface ICF1 adjacent to the light emitting area, a second inclined surface ICF2 facing the first inclined surface ICF1, an upper surface UF connecting the first inclined surface ICF1 and the second inclined surface ICF2, and a lower surface LF in contact with the surface of the overcoat layer OC. The first inclined surface ICF1 may be an inner side surface of the conductive pattern CP, and the second inclined surface ICF2 may be an outer side surface of the conductive pattern CP.

A first taper angle θ1 of the first inclined surface ICF1 of the conductive pattern CP may be 90° or less. The first inclined surface ICF1 of the conductive pattern CP may be formed of a forward-tapered structure. The first taper angle θ1 may be inclination angle of the first inclined surface ICF1, and may refer to an angle formed by the overcoat layer OC and the first inclined surface ICF1 of the conductive pattern CP.

A height H from the surface of the overcoat layer OC to the upper surface UF of the conductive pattern CP may be a thickness of the conductive pattern CP. The conductive pattern CP may have a constant thickness to secure the first and second inclined surfaces ICF1 and ICF2. For example, the thickness of the conductive pattern CP may be about 0.5 μm, but is not limited thereto.

The first inclined surface ICF1 of the two conductive patterns CP spaced apart by a predetermined width W in each sub-pixel may be located outside than the side surface of the third insulating layer INS3 facing each other with the opening OP therebetween. For example, the first inclined surface ICF1 of the two conductive patterns CP spaced apart from each other by the predetermined width W in the second sub-pixel SP2 may be located outside than the side surface (or the edge) of the third insulating layer INS3 (or the pixel defining layer PDL) facing each other with the opening OP therebetween.

A gap between the first encapsulation layer ENC1 and the conductive pattern CP may correspond to a thickness d of the overcoat layer OC. The thickness d of the overcoat layer OC may be about 1 μm to 5 μm, but is not limited thereto.

Of light emitted from each of the first to third light emitting structures EMS1 to EMS3, the light that is incident upon the first inclined surface ICF1 of the conductive pattern CP may be reflected to the light emitting area of each sub-pixel by the first inclined surface ICF1. In this case, the light emitted from each sub-pixel in the front direction may be increased, so that the front light emission efficiency of each sub-pixel may be improved. For example, of the light LT emitted from the second light emitting structure EMS2, the light LT incident upon the first inclined surface ICF1 of the conductive pattern CP may be reflected by the first inclined surface ICF1 to the second light emitting area EMA2 of the second sub-pixel SP2. In this case, the amount of light LT emitted from the second sub-pixel SP2 in the front direction may be increased, so that the front light emission efficiency of the second sub-pixel SP2 may be improved.

As the conductive pattern CP is directly disposed on the overcoat layer OC on the second light emitting structure EMS2, the gap between the conductive pattern CP and the second light emitting structure EMS2 (or light source) may be relatively close compared to a conventional display device in which a reflective member is disposed on the second encapsulation layer ENC2. In this case, among light emitted from the light source, even light proceeding at a low angle may be guided in the front direction compared to the conventional display device. Accordingly, the front light emission efficiency of the second sub-pixel SP2 may be improved.

The conductive pattern CP may be disposed on the overcoat layer OC through an etching process using a mask or the like. Because the first to third light emitting structures EMS1 to EMS3 are respectively sealed by the capping layer CPL and the first encapsulation layer ENC1, the first to third light emitting structures EMS1 to EMS3 may not be affected when the above-described process is performed.

A second encapsulation layer ENC2 may be disposed on the conductive pattern CP and the overcoat layer OC. The second encapsulation layer ENC2 may include an organic film including an organic material. The organic film may include an organic insulating material such as polyacrylate resins, epoxy resins, phenolic resins, polyamide resins, polyimide resins, unsaturated polyester resins, poly-phenylene ether resins, poly-phenylene sulfide resins, and benzocyclobutene resins. The second encapsulation layer ENC2 may have a relatively thicker thickness than the first encapsulation layer ENC1 and the overcoat layer OC. For example, the second encapsulation layer ENC2 may have a thickness of about 7 μm in the third direction DR3, but is not limited thereto. The second encapsulation layer ENC2 may have a flat surface.

A third encapsulation layer ENC3 may be disposed on the second encapsulation layer ENC2. The third encapsulation layer ENC3 may be an inorganic film including an inorganic material. The third encapsulation layer ENC3 may be disposed on the second encapsulation layer ENC2 to prevent oxygen, moisture, or the like from penetrating into the second encapsulation layer ENC2 from the outside. The third encapsulation layer ENC3 may have a thickness of about 1 μm in the third direction DR3, but is not limited thereto.

The first encapsulation layer ENC1, the second encapsulation layer ENC2, and the third encapsulation layer ENC3 may form an encapsulation layer TFE.

A touch sensing layer TSL may be disposed on the display element layer DPL. The touch sensing layer TSL may include a base layer BSL, a first touch insulating layer T_INS1, a sensing electrode SSE, and a second touch insulating layer T_INS2.

The base layer BSL may be the third encapsulation layer ENC3 of the encapsulation layer ENC. In this case, the base layer BSL may be an inorganic film including an inorganic material.

The first touch insulating layer T_INS1 may be disposed on the base layer BSL. The first touch insulating layer T_INS1 may be an inorganic film including an inorganic material or an organic film including an organic material. For example, the first touch insulating layer T_INS1 may be the inorganic film.

The sensing electrode SSE may be disposed on the first touch insulating layer T_INS1. The sensing electrode SSE (or a sensing pattern) may be disposed between the first touch insulating layer T_INS1 and the second touch insulating layer T_INS2. In addition, the sensing electrode SSE may be disposed between the base layer BSL and the first touch insulating layer T_INS1. The sensing electrode SSE may be a touch electrode that recognize a touch event of the display device DD through a user's hand or a separate input means.

A light functional layer LFL may be disposed on the touch sensing layer TSL. The light functional layer LFL may include a polarizing member that converts a polarizing state of light emitted from each of the first to third sub-pixels SP1 to SP3, but is not limited thereto. According to embodiments, the light functional layer LFL may further include a color filter layer including a color filter and color conversion patterns with color conversion particles or scattering particles.

A window WD may be disposed on the light functional layer LFL. The window WD may protect the touch sensing layer TSL from external impacts. The window WD may be attached to the light functional layer LFL using an optical transparent adhesive member. The window WD may have multilayer structures selected from a glass substrate, a plastic film, and a plastic substrate. These multilayer structures may be formed through a continuous process or an adhesive process using adhesive layers. An entirety of the window WD or a portion of the window WD may be flexible.

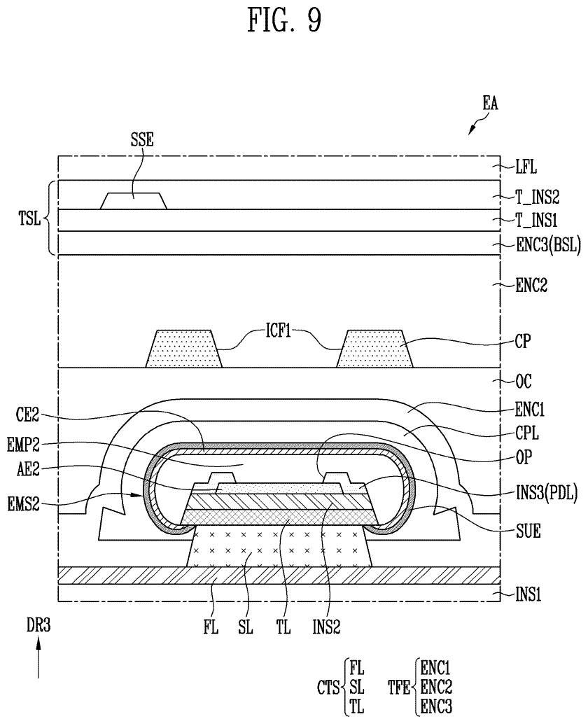

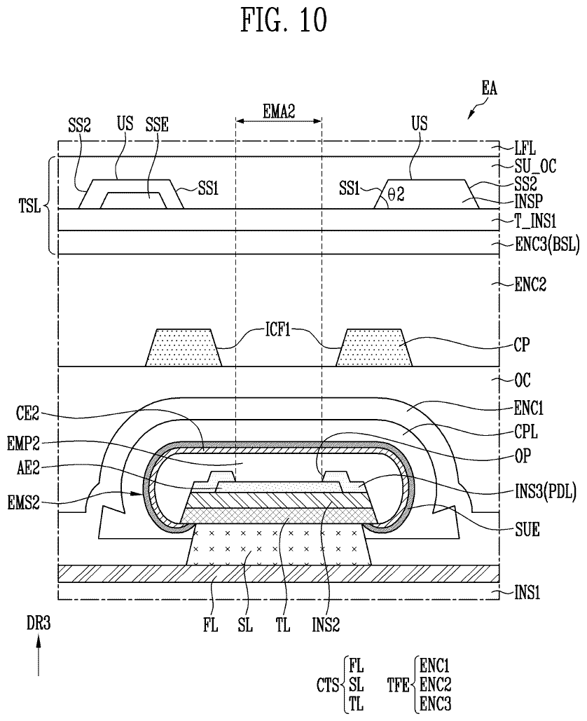

FIG. 9 and FIG. 10 are schematic enlarged cross-sectional views illustrating an area EA of FIG. 6.

With respect to the embodiments of FIG. 9 and FIG. 10, redundant description with the above-described embodiments will be omitted for convenience of explanation.

Referring to FIG. 6, FIG. 9, and FIG. 10, the second light emitting structure EMS may further include an auxiliary electrode SUE for a coupling force between the second cathode electrode CE2 and the contact structure CTS.

The auxiliary electrode SUE may include the same material as the second cathode electrode CE2. For example, the auxiliary electrode SUE may include a transparent conductive material. The auxiliary electrode SUE may be disposed between the second cathode electrode CE2 and the capping layer CPL. The auxiliary electrode SUE may be in direct contact with the side surface (or edge) of the second layer SL of the contact structure CTS or a bottom surface of the third layer TL of the contact structure CTS.

A touch sensing layer TSL may include a base layer BSL, a first touch insulating layer T_INS1, a sensing electrode SSE, an insulating pattern INSP, and a sub overcoat layer SU_OC.

The base layer BSL may be the third encapsulation layer ENC3 of the encapsulation layer ENC. The first touch insulating layer T_INS1 may be disposed on the base layer BSL. The sensing electrode SSE may be disposed on the first touch insulating layer T_INS1.

The insulating pattern INSP may be formed by removing a portion of the second touch insulating layer T_INS2 described with reference of FIG. 6 and FIG. 7. The insulating pattern INSP may not overlap the light emitting area of each sub-pixel. For example, the insulating pattern INSP may not overlap the second light emitting area EMA2 of the second sub-pixel (see “SP2” in FIG. 6). The insulating pattern INSP may include a first side surface SS1 (or a first inclined surface) adjacent to the second light emitting area EMA2, a second side surface SS2 (or a second inclined surface) facing the first side surface SS1, an upper surface US connecting the first side surface SS1 and the second side surface SS2. The first side surface SS1 may be an inner side surface of the insulating pattern INSP, and the second side surface SS2 may be an outer side surface of the insulating pattern INSP.

A second taper angle θ2 of the first side surface SS1 of the insulating pattern INSP may be 90° or less. The first side surface SS1 of the insulating pattern INSP may be formed of a forward-tapered structure. The second taper angle θ2 may be the same as or different from the first taper angle θ1 of the conductive pattern CP.

The first side surface SS1 of the insulating pattern INSP may be positioned outside than the first inclined surface (see “ICF1” in FIG. 7) of the conductive pattern CP. For example, the first side surface SS1 of the insulating pattern INSP may be disposed on the sensing electrode SSE or the first touch insulating layer T_INS1 so as to be further away from the second light emitting area EMA2 than the first inclined surface ICF1 of the conductive pattern CP.

The sub overcoat layer SU_OC may be disposed on the insulating pattern INSP. The sub overcoat layer SU_OC may have the same material as the overcoat layer OC. A refractive index of the sub overcoat layer SU_OC may be greater than a refractive index of the insulating pattern INSP. For example, the insulating pattern INSP may have a refractive index of about 1.53, and the sub overcoat layer SU_OC may have a refractive index of about 1.62, but is not limited thereto.

Light emitted from the second light emitting structure EMS2 may be emitted to the front surface of the second sub-pixel SP2 (or the second light emitting area EMA2). Among light emitting from the second light emitting structure EMS2, light proceeding to the first side surface SS1 of the insulating pattern INSP may be reflected to the second light emitting area EMA2 of the second sub-pixel SP2 by the first side surface SS1. In this case, the amount of light emitted from the second sub-pixel SP2 in the front direction may be increased, so that the front light emission efficiency of the second sub-pixel SP2 may be improved.

As the insulating pattern INSP has a smaller refractive index than the sub overcoat layer SU_OC disposed directly above it, total reflection effect due to a refractive difference at an interface between the insulating pattern INSP and the sub overcoat layer SU_OC may be improved.

Hereinafter, a method of manufacturing the display device according to the above-described embodiments will be described.

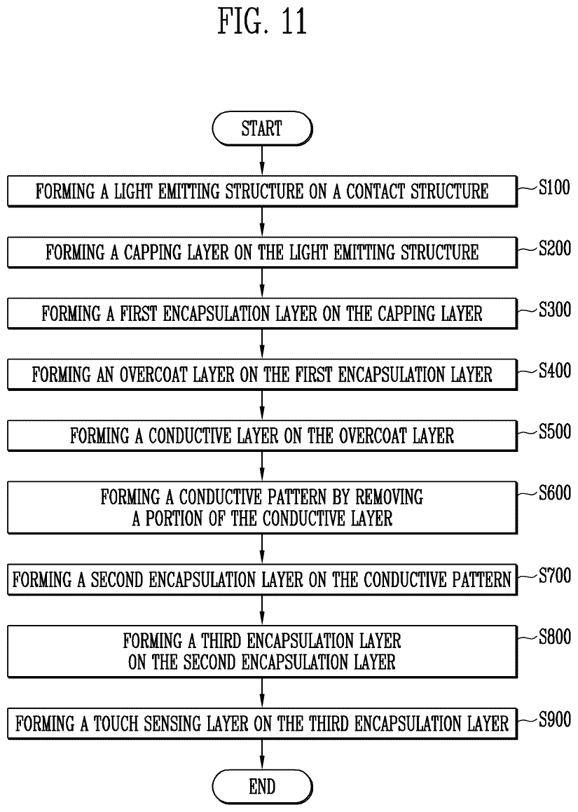

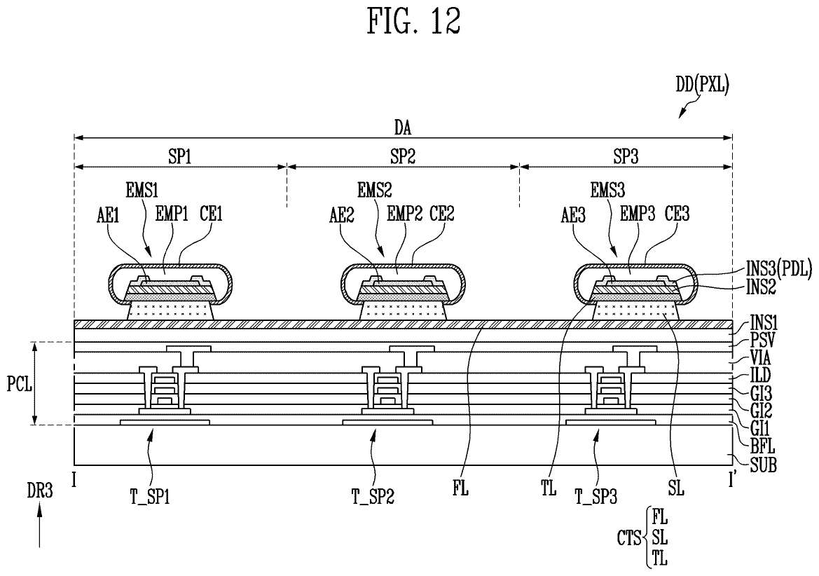

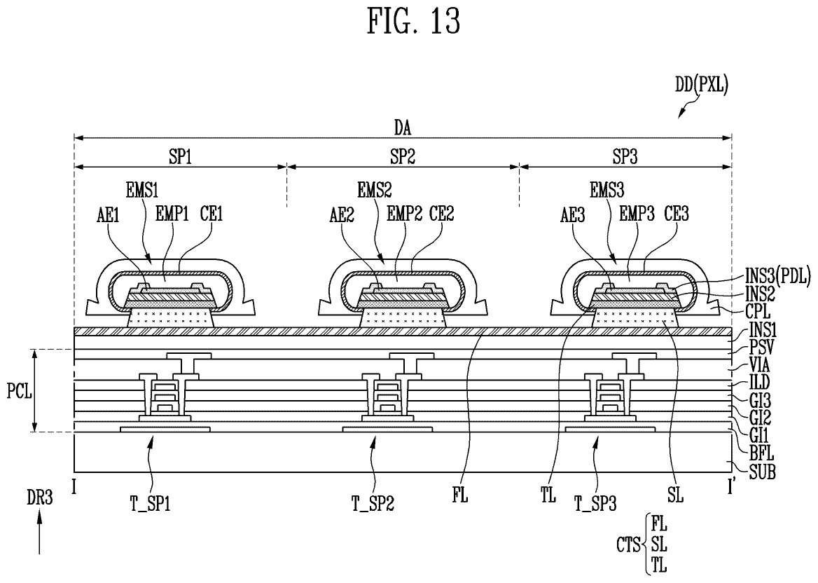

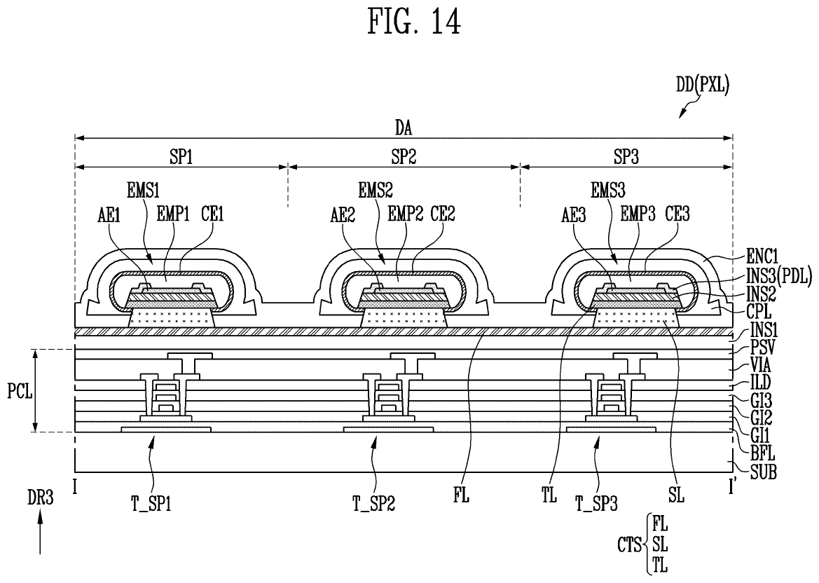

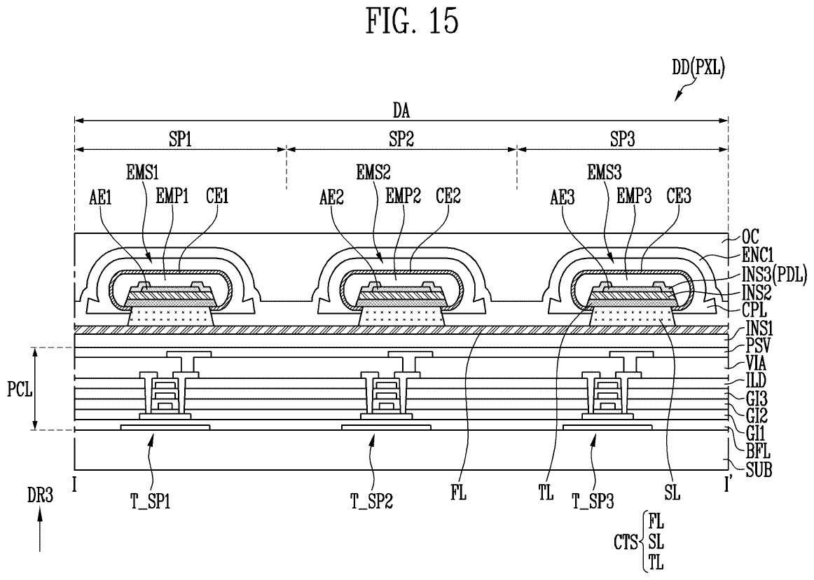

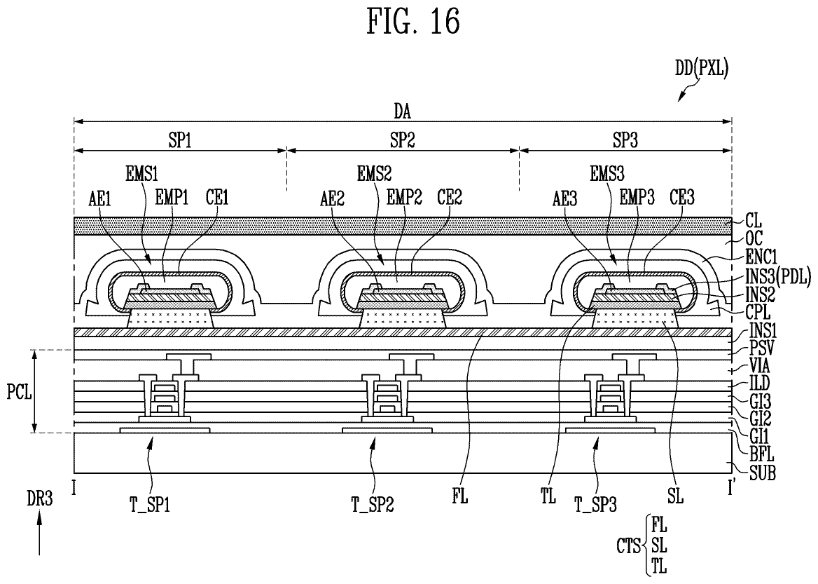

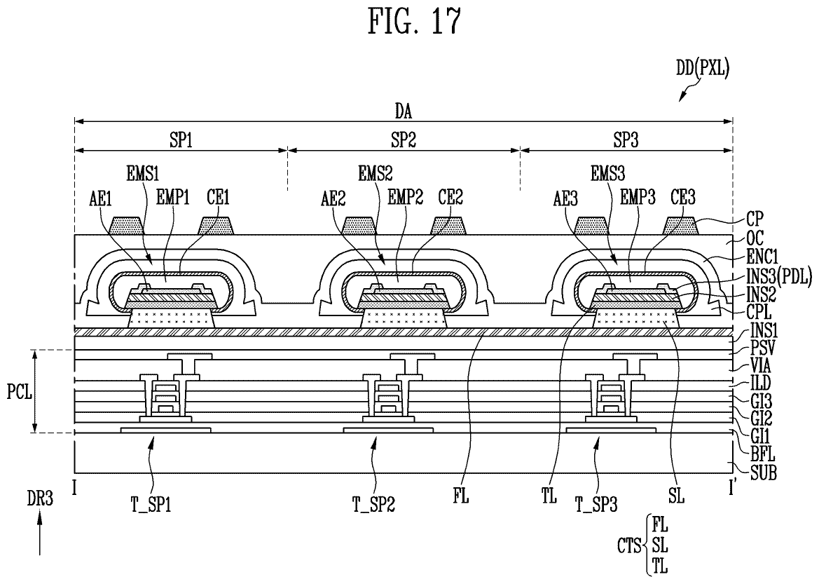

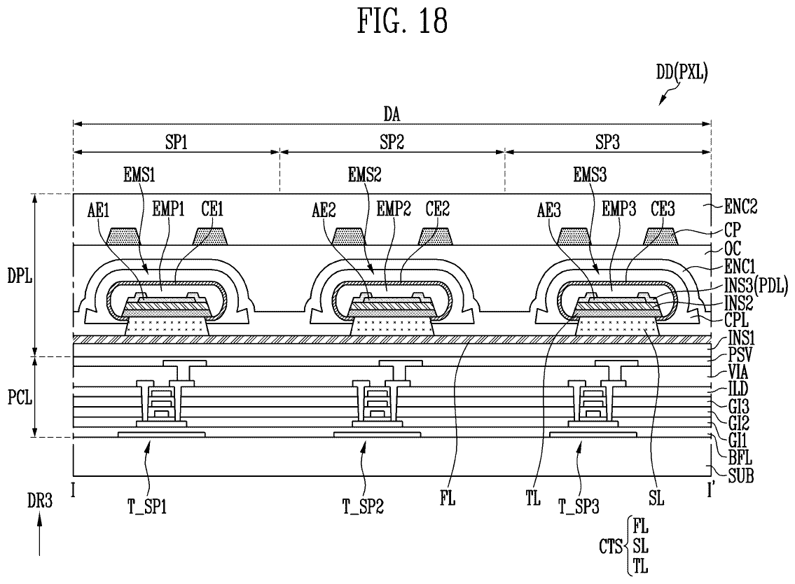

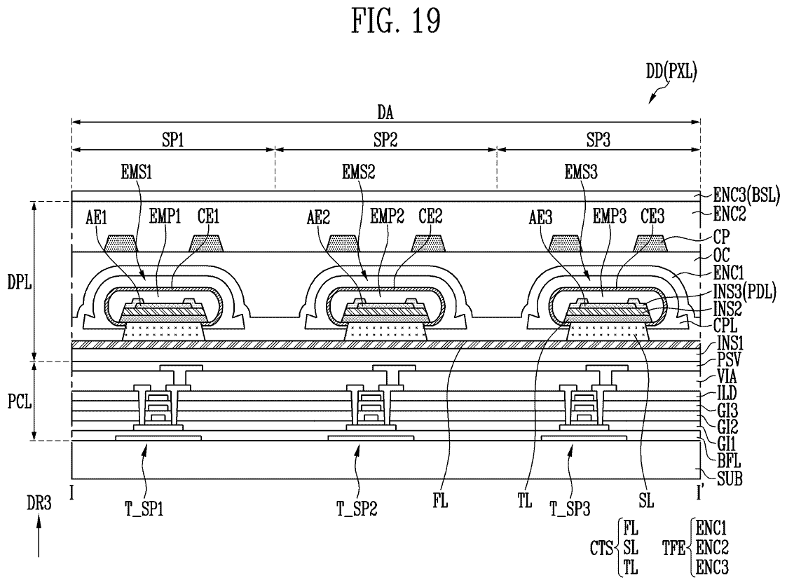

FIG. 11 is a flowchart illustrating a method of manufacturing a display device according to embodiments. FIG. 12 to FIG. 20 are schematic cross-sectional views illustrating process steps of a method of manufacturing a display device according to embodiments.

In embodiments shown in FIG. 11 to FIG. 20, although it is described that steps of manufacturing the display device DD are sequentially performed, without changing the spirit of the disclosure, some steps illustrated as being successively performed may be simultaneously performed, the sequence of the steps may be changed, some steps may be omitted, or another step may be further included between the steps.

With respect to the embodiments of FIG. 11 to FIG. 20, redundant description with the above-described embodiments will be omitted for convenience of explanation.

Referring to FIG. 11 and FIG. 12, first to third light emitting structures EMS1 to EMS3 are formed on a contact structure CTS. (S100)

The contact structure CTS may include a first layer FL, a second layer SL, and a third layer TL.

The first light emitting structure EMS1 may include a first anode electrode AE1, a first light emitting pattern EMP1, a first cathode electrode CE1. The second light emitting structure EMS2 may include a second anode electrode AE2, a second light emitting pattern EMP2, a second cathode electrode CE2. The third light emitting structure EMS3 may include a third anode electrode AE3, a third light emitting pattern EMP3, a third cathode electrode CE3.

Referring to FIG. 11 to FIG. 13, a capping layer CPL is formed on each of the first to third light emitting structures EMS1 to EMS3. (S200)

The capping layer CPL may be disposed on the cathode electrode of each the first to third light emitting structures EMS1 to EMS3 to entirely cover the first to third light emitting structures EMS1 to EMS3.

The capping layer CPL on the first light emitting structure EMS1, the capping layer CPL on the second light emitting structure EMS2, and the capping layer CPL on the third light emitting structure EMS3 may be separated from each other.

Referring to FIG. 11 to FIG. 14, a first encapsulation layer ENC1 is formed on the capping layer CPL. (S300)

The first encapsulation layer ENC1 may entirely cover the capping layer CPL and the first to third light emitting structures EMS1 to EMS3. The first encapsulation layer ENC1 may be an encapsulation member that seals each of the first to third light emitting structures EMS1 to EMS3 together with the capping layer CPL.

Referring to FIG. 11 to FIG. 15, an overcoat layer OC is formed on the first encapsulation layer ENC1. (S400)

A gap between the first encapsulation layer ENC1 and a surface of the overcoat layer OC (or a thickness of the overcoat layer OC (see “d” in FIG. 7)) may be about 1 μm to 5 μm, but is not limited thereto.

Referring to FIG. 11 to FIG. 16, a conductive layer CL is formed on the overcoat layer OC. (S500)

The conductive layer CL may include a metal that guides (or reflects) light emitted from the first to third light emitting structures EMS1 to EMS3 in a front direction (or light emitting area) of each of the first to third sub-pixels SP1 to SP3.

Referring to FIG. 11 to FIG. 17, a photolithography process using a mask is performed to remove a portion of the conductive layer CL to form a conductive pattern CP on the overcoat layer OC (S600).

The conductive pattern CP may be disposed on the overcoat layer OC so as not to overlap the light emitting area in each sub-pixel.

Because the first to third light emitting structures EMS1 to EMS3 are sealed for each sub-pixel by the capping layer CPL and the first encapsulating layer ENC1, the first to third light emitting structures EMS1 to EMS3 may not be affected during the above-described process is performed.

Referring to FIG. 11 to FIG. 18, a second encapsulation layer ENC2 is formed on the conductive pattern CP. (S700)

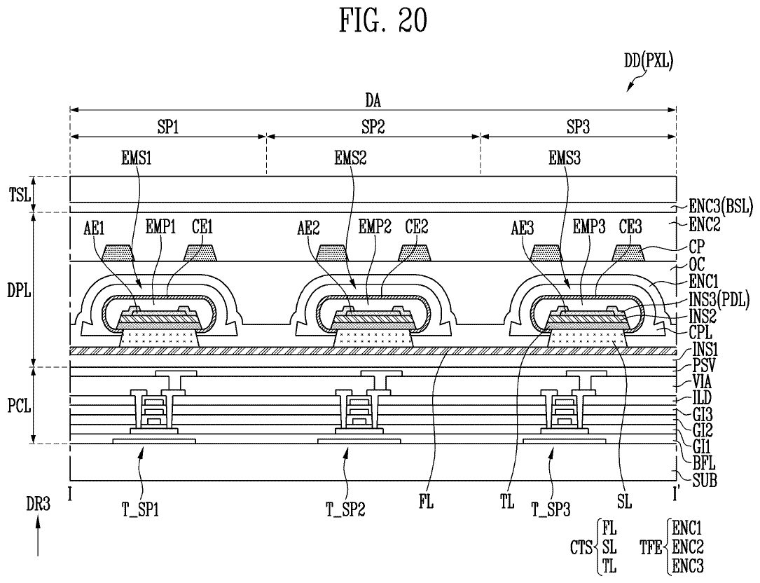

The second encapsulation layer ENC2 may secure a gap between the conductive pattern CP and a touch sensing layer (see “TSL” in FIG. 20) and seal the conductive pattern CP and the overcoat layer OC.

Referring to FIG. 11 to FIG. 19, a third encapsulation layer ENC3 is formed on the second encapsulation layer ENC2. (S800)

The third encapsulation layer ENC3 may be an inorganic film including an inorganic material. The third encapsulation layer ENC3 may be disposed on the second encapsulation layer ENC2 to prevent oxygen, moisture, or the like from penetrating into the second encapsulation layer ENC2.

Referring to FIG. 11 to FIG. 20, the touch sensing layer TSL is formed on the third encapsulation layer ENC3. (S900)

In embodiments, the third encapsulation layer ENC3 may be a base layer BSL of the touch sensing layer TSL. Some sensing electrode SSE of the touch sensing layer TSL may be disposed directly on the third encapsulation layer ENC3 (or the base layer BSL).

The display device DD according to embodiments may be applied to various electronic devices. An electronic device according to embodiments may include the display device DD described above, and may further include modules or devices having an additional function other than the display device DD.

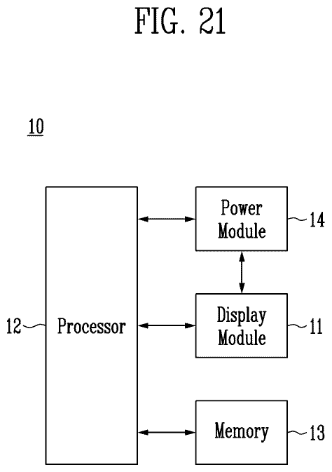

FIG. 21 is a schematic block diagram illustrating an electronic device 10 in accordance with embodiments of the disclosure.

Referring to FIG. 21, the electronic device 10 in accordance with embodiments of the disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data or information used to operate the processor 12 or the display module 11. When the processor 12 executes an application stored in the memory 13, image data signals or input control signals may be transferred to the display module 11. The display module 11 may process the provided signals and output image information on a display screen.

The power module 14 may include a power supply module, such as a power adapter or a battery device, and conversion module. The power conversion module convers power supplied by the power supply module and generates power to operate the electronic device 10.

At least one of the above-described components of the electronic device 10 may be included in the display device 100 according to embodiments as described above. In addition, in terms of functionality, some of the individual modules included in one module may be included in the display device 100 and others may be provided separately from the display device. For example, the display module 11 is included in the display device, whereas the processor 12, the memory 13, and the power module 14 are not included in the display device and are instead provided separately in the electronic device 10.

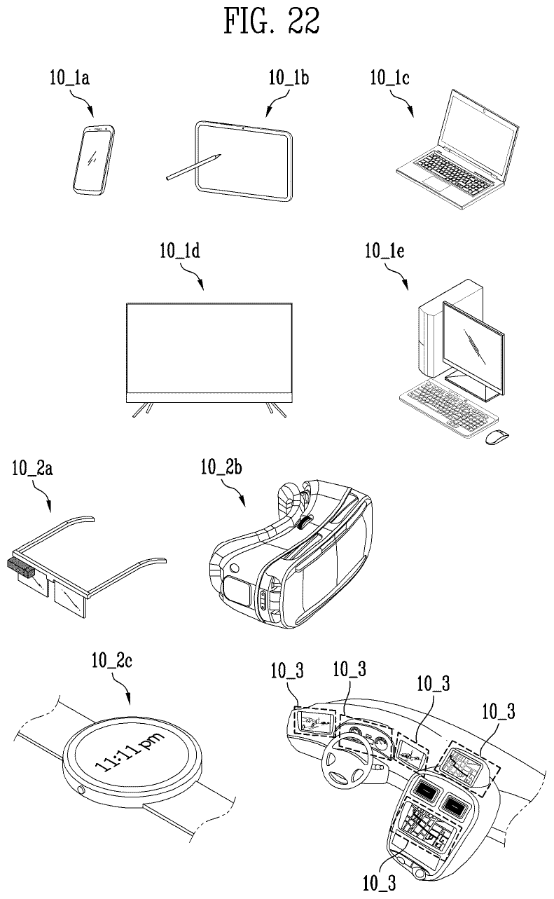

FIG. 22 shows schematic views of various embodiments of an electronic device.

Referring to FIG. 22, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as a smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, or elements described in connection with a particular embodiment may be used singly or in combination with features, characteristics, or elements described in connection with other embodiments unless otherwise specifically indicated.

Accordingly, it will be understood by those skilled in the art that various changes in form and details may be made without departing from the spirit and scope of the disclosure as set forth in the following claims.

What is claimed is:

1. A display device comprising:
a substrate including a plurality of sub-pixels;
a contact structure disposed in each of the plurality of sub-pixels;
a light emitting structure disposed on the contact structure of each of the plurality of sub-pixels;
a first encapsulation layer disposed on the light emitting structure and including an inorganic material;
an overcoat layer disposed on the first encapsulation layer;
a conductive pattern disposed on the overcoat layer, the conductive pattern does not overlap a light emitting area of each of the plurality of sub-pixels;
a second encapsulation layer disposed on the conductive pattern and including an organic material; and
a third encapsulation layer disposed on the second encapsulation layer.

2. The display device of claim 1, wherein the conductive pattern is disposed between the overcoat layer and the second encapsulation layer,
wherein the conductive pattern includes a first inclined surface adjacent to the light emitting area, a second inclined surface facing the first inclined surface, and an upper surface connecting the first inclined surface and the second inclined surface, and
wherein the first inclined surface guides light emitted from the light emitting structure to the light emitting area of each of the sub-pixels.

3. The display device of claim 1, wherein the conductive pattern has a height of about 0.5 μm or more from a surface of the overcoat layer.

4. The display device of claim 1, wherein a gap between the first encapsulation layer and the overcoat layer is about 1 μm to 5 μm.

5. The display device of claim 1, wherein the light emitting structure is completely covered by the first encapsulation layer.

6. The display device of claim 2, wherein the light emitting structure includes:
an anode electrode disposed on the contact structure;
a pixel defining layer disposed on the anode electrode and including an opening that exposes a portion of the anode electrode to define the light emitting area;
a light emitting pattern disposed between the pixel defining layer and the anode electrode; and
a cathode electrode disposed on the light emitting pattern.

7. The display device of claim 6, wherein the first inclined surface is located outside a side surface of the pixel defining layer defining the opening.

8. The display device of claim 6, wherein the contact structure includes:
a first layer disposed on the substrate;
a second layer disposed on the first layer; and
a third layer disposed between the second layer and the light emitting structure, wherein the first to third layers include a conductive material and are electrically connected to each other.

9. The display device of claim 8, wherein at least one of the first layer, the second layer, and the third layer is in contact with the cathode electrode.

10. The display device of claim 6, wherein the light emitting structure further includes a sub-electrode disposed on the cathode electrode.

11. The display device of claim 6, further comprising:
a capping layer disposed between the cathode electrode and the first encapsulation layer,
wherein the capping layer is disposed on the cathode electrode to seal the light emitting structure.

12. The display device of claim 1, further comprising:
a touch sensing layer disposed on the third encapsulation layer,
wherein the touch sensing layer includes:
a sensing pattern disposed on the third encapsulation layer; and
an insulating pattern disposed on the sensing pattern to cover a touch conductive pattern.

13. The display device of claim 12, wherein the insulating pattern includes a side surface that guides light emitted from the light emitting structure toward a front direction.

14. The display device of claim 12, further comprising:
a sub-overcoat layer disposed on the touch sensing layer,
wherein a refractive index of the sub-overcoat layer is greater than a refractive index of the insulating pattern.

15. An electronic device comprising:
a processor; and
a display device including sub-pixels and configured to display an image based on the control of the processor,
wherein the display device includes:
a substrate including the sub-pixels;
a contact structure disposed in each of the sub-pixels of the substrate;
a light emitting structure disposed on the contact structure of each of the sub-pixels;
a first encapsulation layer disposed on the light emitting structure and including an inorganic material;
an overcoat layer disposed on the first encapsulation layer;
a conductive pattern dispose on the overcoat layer, the conductive pattern that does not overlap a light emitting area of each of the sub-pixels;
a second encapsulation layer disposed on the conductive pattern; and
a third encapsulation layer disposed on the second encapsulation layer.

16. The electronic device of claim 15, wherein the conductive pattern is disposed between the overcoat layer and the second encapsulation layer, and
wherein the conductive pattern includes a first inclined surface that guides light emitted from the light emitting structure in a front direction.

17. The electronic device of claim 15, wherein the conductive pattern has a height of about 0.5 μm or more from a surface of the overcoat layer.

18. The electronic device of claim 15, wherein the light emitting structure includes:
an anode electrode disposed on the contact structure;
a pixel defining layer disposed on the anode electrode and including an opening that exposes a portion of the anode electrode to define the light emitting area;
a light emitting pattern disposed between the pixel defining layer and the anode electrode; and
a cathode electrode disposed on the light emitting pattern.

19. The electronic device of claim 18, wherein the contact structure includes:
a first layer disposed on the substrate;
a second layer disposed on the first layer; and
a third layer disposed between the second layer and the light emitting structure,
wherein at least one of the first layer, the second layer, and the third layer is in contact with the cathode electrode.

20. A method of manufacturing a display device, the method comprising:
providing a substrate;
forming a contact structure on the substrate;
forming a light emitting structure on the contact structure;
forming a first encapsulation layer on the light emitting structure;
forming an overcoat layer on the first encapsulation layer;
forming a conductive layer on the overcoat layer;
forming a conductive pattern by removing a portion of the conductive layer through a process using a mask;
forming a second encapsulation layer on the conductive pattern and the overcoat layer; and
forming a third encapsulation layer on the second encapsulation layer,
wherein the conductive pattern is disposed between the overcoat layer and the second encapsulation layer, and includes an inclined surface that guides light emitted from the light emitting structure in a front direction.
